(19) United States
(12) Patent Application Publication
(10) Pub. No.: US 2024/0302542 A1
(43) Pub. Date: Sep. 12, 2024

(54) PARTICLE BEAM MICROSCOPE

(71) Applicant: Carl Zeiss Microscopy GmbH, Jena (DE)

(72) Inventors: Erik Essers, Aalen (DE); Dirk Preikszas, Oberkochen (DE)

(21) Appl. No.: 18/600,229

(22) Filed: Mar. 8, 2024

(30) Foreign Application Priority Data
Mar. 10, 2023 (DE) 10 2023 106 027.9

(51) Int. Cl. G01T 1/20; H01J 37/10

(52) U.S. Cl. CPC G01T 1/2018; G01T 1/2002; H01J 37/10

(57) ABSTRACT

A particle beam microscope comprises: a particle beam source for generating a particle beam; an objective lens for focusing the particle beam in an object plane; a first scintillator for converting electrons into light; a second scintillator for generating light by way of electrons; and light detectors for detecting the generated light. The distance of second scintillator from the object plane is greater than the distance of the first scintillator from the object plane. The second scintillator has a surface which faces the object plane and through which electrons arriving from the object plane pass. The electrons are converted into light by the second scintillator. The light generated by the first scintillator and detected by a light detector is incident on the second scintillator.

### CROSS-REFERENCE TO RELATED APPLICATION

This application claims benefit under 35 U.S.C. § 119 to German Application No. 10 2023 106 027.9, filed Mar. 10, 2023. The entire disclosure of this application is incorporated by reference herein.

### FIELD

The present disclosure relates to a particle beam microscope, such as a particle beam microscope comprising a particle beam source, an objective lens, a scintillator and a light detector. The particle beam source generates a particle beam by generating and accelerating charged particles, such as electrons or ions, and shaping them into a particle beam. The objective lens focuses this particle beam on the surface of an object to form a small beam spot. The particles of the particle beam that impinge on the object interact with the object, wherein the type and extent of the interaction depend on the properties of the object at the particle beam incidence location. The scintillator and the light detector form a detection system for particles generated on account of the interaction at the object. On the basis of the detection of these particles, it is possible to obtain information concerning the properties of the object, such as, for instance, structure and chemical composition. The detected particles include electrons which are generated in the proximity of the surface of the object as a result of the incidence of the particles of the particle beam and emerge from the object. Upon their exit from the object, these electrons have very different kinetic energies, from a few electron volts right up to the kinetic energy of the particles in the incident particle beam which, depending on application, may be several kiloelectron volts.

### BACKGROUND

Electrons emerging from an object impinge on a scintillator, which is configured to generate light if an electron impinges on the scintillator or penetrates into the latter. The intensity of the generated light increases with the intensity of the electrons impinging on the scintillator. Part of the light generated by the scintillator is detected by the light detector and converted into electrical detection signals, which can be read in and analysed by a controller of the particle beam microscope. The intensity of the detected light can represent the intensity of the electrons that are generated by the particle beam at the object and emerge from the latter and may yield valuable information concerning the properties of the object at the particle beam incidence location.

Besides the intensity of the electrons generated at the object, their kinetic energy is also of interest in order to acquire information concerning the properties of the object. For this purpose, it is conventional practice to use energy filters, for example, which select the electrons that arise at the object before their detection with regard to their kinetic energy in order to be able to determine the intensity of the generated electrons depending on the kinetic energy thereof. Particle beam microscopes are known which comprise a plurality of different detectors configured to selectively detect different types of electrons generated at the object. The different detectors differ from one another substantially in terms of their spatial positioning in the particle beam microscope and the electric potential of their electron receiver surfaces.

### SUMMARY

It is not easy to integrate a plurality of electron detectors with electron receiver surfaces at different electric potentials into one particle beam microscope since the electric potentials of the detectors also influence the shape of the particle beam incident on the object and its kinetic energy.

The present disclosure proposes a particle beam microscope having a plurality of different detectors which allow good focusing of the particle beam on the object and enable the high detection probability detection of electrons at different energies emanating from the object.

According an aspect to the disclosure, a particle beam microscope comprises a particle beam source for generating a particle beam, an objective lens for focusing the particle beam, a first scintillator configured to generate light by way of electrons arriving from the object, a second scintillator different from the first scintillator and configured to generate light by way of electrons arriving from the object, and at least one light detector configured to detect light generated by the first scintillator and/or the second scintillator. The provision of the two different scintillators renders it possible to detect different types of electrons arriving from the object. For example, the two types of electrons may differ in terms of the kinetic energy with which they emanate from the object and/or in terms of the direction that their trajectories are oriented in upon departure from the object.

The electrons can generate light in the first and in the second scintillator by virtue of some of their kinetic energy being converted into light in the scintillator material of a scintillator body of the scintillator.

According to exemplary embodiments, a shortest distance of the second scintillator from the object plane is greater than a shortest distance of the first scintillator from the object plane. The shortest distance of the scintillator from the object plane is determined as the distance of the scintillator from the object plane at the location which, from all geometric locations where the scintillator body is present, has the shortest distance from the object plane. Thus, the second scintillator has a greater distance from the object plane than the first scintillator. For example, the distance of the second scintillator from the object plane may be five times, ten times or twenty times greater than the distance of the first scintillator from the object plane. In this case, different types of electrons arriving from the object plane are incident on the two different scintillators. A reason for this can be found in the different positioning of the two scintillators relative to the object plane.

According to exemplary embodiments, the first and the second scintillator each have a surface facing the object plane, on which electrons arriving from the object plane are incident and through which the electrons penetrate into the volume of the scintillator. During the incidence on the surface and the penetration into the volume of the scintillator, the scintillator material of the scintillator generates light which is detectable by the at least one light detector. The light generated by the scintillator departs the location of generation in many possible directions and not necessarily in the direction towards the light detector. Therefore, a large proportion of the light generated by the electrons is not detected and there is also the desire for the first and the second scintillator and the at least one light detector to be configured such that, of the light generated by the first and the second scintillator by way of the electrons, a portion that is as large as possible can be detected by the at least one light detector.

According to exemplary embodiments, there is a plane cross-sectional area which is arranged across a beam direction of the particle beam and in which a first beam path and a second beam path overlap, wherein the first beam path is the beam path of electrons arriving from the object plane, by which the second scintillator generates light, and wherein the second beam path is the beam path of light which is generated by the first scintillator and detected by the at least one light detector. The two beam paths overlap within the sense that the cross-sectional area contains locations which are passed both by the electrons arriving from the object plane and by the light generated by the first scintillator. As a result, some of the space located between the second scintillator and the object plane is used both to supply the second scintillator with electrons to be detected and to supply the at least one light detector with light generated in the first scintillator. On account of this use of the generally very restricted installation space in the vicinity of the scintillators of the particle beam microscope, it is possible to improve the detection of electrons generated at the object by way of the two different scintillators.

According to exemplary embodiments, the at least one light detector comprises a first light detector configured to detect the light generated by the first scintillator. Further, a mirror surface which reflects the light generated by the first scintillator is arranged in the beam path between the first scintillator and the first light detector. The mirror surface can be supported on the second scintillator. In particular, the mirror surface may be provided directly on the surface of a scintillator body of the second scintillator. As a result, the surface region of the second scintillator is used firstly as electron receiver surface of the second scintillator for the electrons arriving from the object plane, as a result of which the second scintillator generates light which can subsequently be detected by the at least one light detector. The surface region of the second scintillator is also used as a mirror for providing the light path between the first scintillator and the at least one light detector. To this end, the portion of the surface region of the second scintillator formed as a mirror surface faces the first scintillator such that the light generated by the first scintillator is reflected at the mirror surface without penetrating into or passing through the second scintillator.

According to exemplary embodiments, the mirror surface is electrically conductive and can be at a fixed electric potential which can be chosen such that it is not an impediment in view of the detection of the electrons by the second scintillator and the focusing of the particle beam in the object plane.

The second scintillator may comprise a single-crystal scintillator whose surface provides at least a portion of the mirror surface.

According to exemplary embodiments, an angle between a surface normal of the mirror surface and a beam direction of the particle beam generated by the particle beam source is in a range between 25° and 65° and in particular in a range between 30° and 60°.

According to exemplary embodiments, the at least one light detector comprises a second light detector configured to detect the light generated by the second scintillator. As a result, the light generated by the two different scintillators is detected by two different light detectors, and so it is easily possible to discriminate between the different types of electrons, which are detected by the different scintillators.

According to exemplary embodiments, the particle beam microscope comprises a light guide which is arranged in a beam path between the second scintillator and the second light detector. The light guide increases the proportion of the light generated in the second scintillator which is detectable by the at least one light detector. According to exemplary embodiments herein, the second scintillator comprises a surface which is opposite the surface region supporting the mirror surface and which is coupled to a surface of the light guide such that light can emerge from the volume of the second scintillator and enter into the volume of the light guide.

According to exemplary embodiments, the light generated by the first scintillator and incident on the surface region of the second scintillator passes through the second scintillator. As a result, it is possible to superimpose the light generated by the first scintillator on the light generated by the second scintillator and subject the light generated by the first scintillator and the light generated by the second scintillator to joint further processing and, for example, simplify the arrangement of the components used, reduce the number of components used or reduce the installation space occupied by the components used as a result. For example, joint processing can consist of the light generated by the first scintillator and the light generated by the second scintillator being fed jointly in a light guide to one or more light detectors. For example, joint processing can also consist of the light generated by the first scintillator and the light generated by the second scintillator being detected using a common light detector, wherein the second scintillator is arranged in a beam path between the first scintillator and the light detector.

According to exemplary embodiments, the surface region of the second scintillator is electrically conductive and transmits the light generated by the first scintillator. For example, the surface region of the second scintillator is not configured in this case to reflect the light generated by the first scintillator. However, in practice, the surface region may be realized such that nevertheless some of the light generated by the first scintillator is reflected at the surface region even though this is not desirable per se since this reduces the detectability of the light generated by the first scintillator by the at least one light detector.

According to exemplary embodiments, an angle between a surface normal of the surface region of the second scintillator and a beam direction of the particle beam generated by the particle beam source is less than 20° and in particular less than 10° or 5°.

According to exemplary embodiments, the particle beam microscope also comprises a light guide arranged in a beam path between the second scintillator and the light detector, wherein a surface of the second scintillator opposite the surface region is optically coupled to a first surface region of the light guide.

According to exemplary embodiments, the light guide comprises a second surface region opposite the first surface region of the light guide, wherein an angle between a surface normal of the first surface region of the light guide and a surface normal of the second surface region of the light guide is in a range between 15° and 55° and in particular in a range between 20° and 50°. Hence, the first and the second surface region delimit the light guide in such a way that the latter has a form which approximates a wedge, which opens towards the light detector and orients the light alternately reflected in the light guide at the first surface region and the second surface region towards the detector. To obtain the form approximating the wedge, a shortest distance between the first surface region and the second surface region can be 5 mm or less, in particular 3 mm or less.

According to exemplary embodiments, the light guide and/or the first scintillator and/or the second scintillator may each have a drilled hole, extending through which is a beam path of the particle beam generated by the particle beam source. Further, the light guide and/or the first scintillator and/or the second scintillator may each be formed in one piece as a continuous body. However, it is also possible that these components are put together from several parts or bodies which together provide the function of the respective component.

According to exemplary embodiments, the particle beam microscope comprises a beam tube, extending through which is the beam path of the particle beam between the second scintillator and the first scintillator, wherein an inner wall of the beam tube is electrically conductive. The beam tube can be at a desired electric potential. As viewed along the beam path of the particle beam generated by the particle beam source, the beam tube extends between a location in the proximity of the particle beam source and a location in the proximity of the object plane.

According to exemplary embodiments, the beam tube comprises a region which is arranged between the second scintillator and the first scintillator and in which the inner wall of the beam tube is a mirror surface. As a result, the beam tube acts as a light guide for the light generated by the first scintillator on its path to the at least one light detector. For example, some of the light generated by the first scintillator is reflected once or multiple times at the inner wall of the beam tube and is ultimately detected by the at least one light detector. For example, the design as mirror surface is realized when a mean surface roughness Ra of the mirror surface is less than 0.4 μm.

According to exemplary embodiments, a first cross-sectional area of the beam tube in an end of the reflective region in the proximity of the first scintillator is smaller than a second cross-sectional area of the beam tube in an end of the reflective region in the proximity of the second scintillator. In this case, the first cross-sectional area and the second cross-sectional area are each determined in a plane orthogonal to the beam direction of the particle beam generated by the particle beam source. For example, the second cross-sectional area can be more than two times larger than the first cross-sectional area. Further, the cross section of the beam tube can increase continuously from the end of the reflective region in the proximity of the first scintillator to the end of the reflective region in the proximity of the second scintillator. This achieves shaping of the directions of the light generated by the first scintillator, with the result that the distribution of the directions of the light is less homogenous and more directed in the direction towards the second scintillator. This alignment of the light generated by the first scintillator can be exploited by virtue of light entrance surfaces, such as surfaces of light guides or surfaces of light detectors, being oriented relative to the preferred direction of the light such that as little light as possible is reflected at these interfaces.

According to exemplary embodiments, the particle beam microscope comprises an object holder configured to hold an object in the object plane, wherein the beam tube has an end in the proximity of the object plane, wherein the first scintillator, as viewed along the beam path of the particle beam, is arranged between the end of the beam tube and the object plane, and wherein the particle beam microscope comprises a potential supply system configured to feed a first potential to the object holder, feed a second potential to the first scintillator and feed a third potential to the electrically conductive inner wall of the beam tube, wherein V2 >V1, V3 >V1 and V2 >V3 applies, where V1 represents the first potential, V2 represents the second potential, and V3 represents the third potential. According to exemplary embodiments, the particle beam microscope also comprises a ring electrode which, as viewed along the beam path of the particle beam, is arranged between the first scintillator and the object plane, wherein the potential supply system is configured to feed a fourth potential V4 to the ring electrode, for which V4 >V1 and V4 >V2 applies.

Embodiments of the disclosure are explained in detail below with reference to figures.

### BRIEF DESCRIPTION OF THE DRAWINGS

### In the Figures:

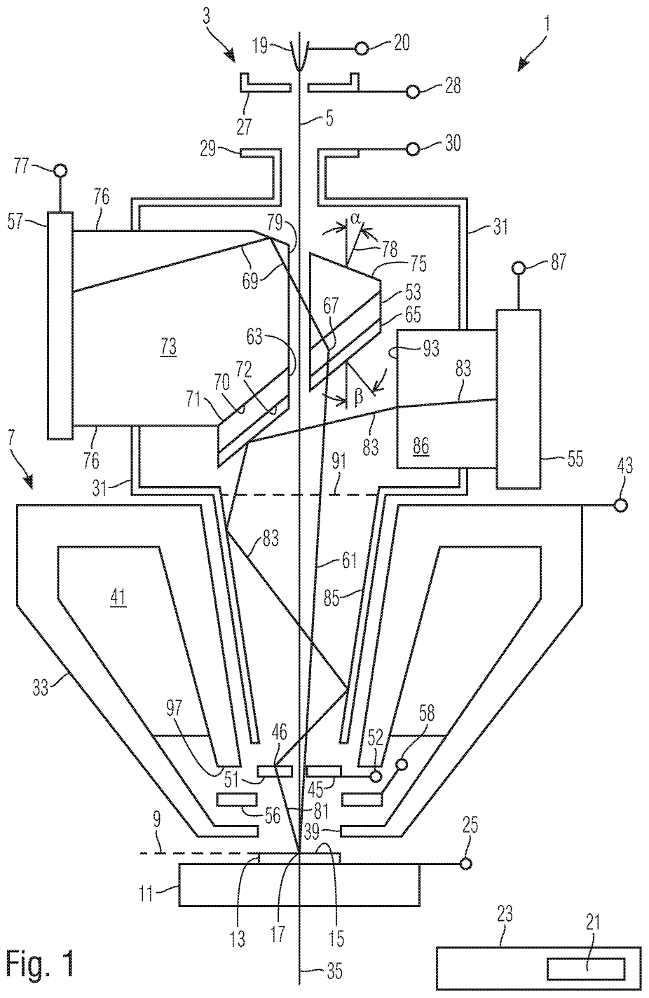

FIG. 1 shows a particle beam microscope according to a first embodiment; and

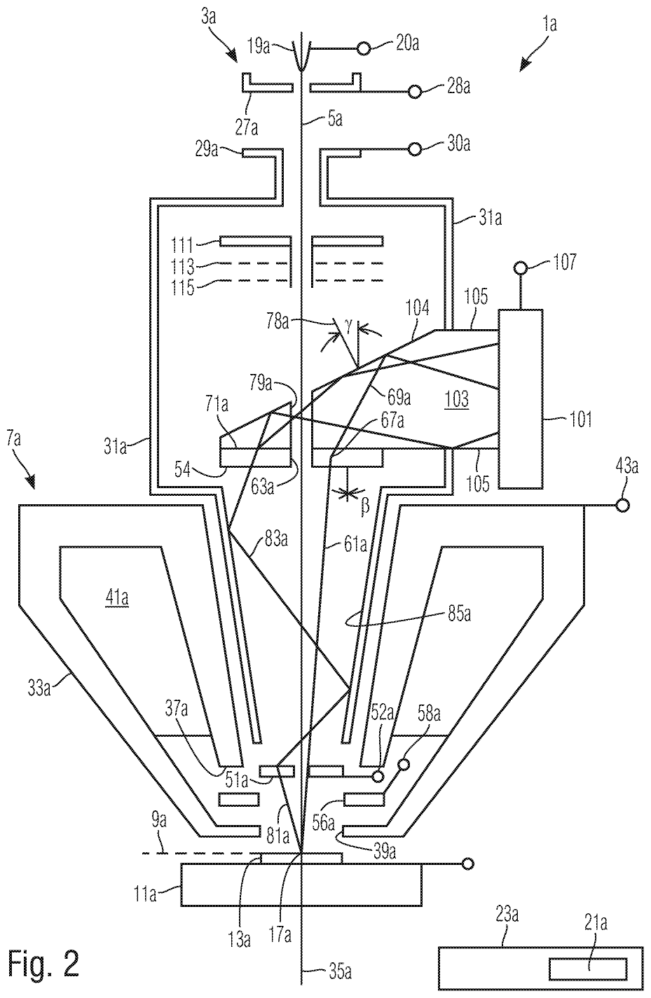

FIG. 2 shows a particle beam microscope according to a second embodiment.

### DETAILED DESCRIPTION

A particle beam microscope 1 shown in FIG. 1 comprises a particle beam source 3 for generating a particle beam 5 and an objective lens 7 for focusing the particle beam 5 in an object plane 9. The particle beam microscope furthermore comprises an object holder 11, which holds an object 13 to be examined such that the surface 15 of the object is arranged in the object plane 9. The particle beam 5 impinging on the object 13 generates electrons at a location 17 at which the particle beam 5 impinges on the surface 15 of the object 13, which electrons emerge from the object 13 and are detected by the particle beam microscope 1, as will be described below.

The particle beam 5 generated by the particle beam source 3 is an electron beam, the particle beam source 3 having a cathode 19 for the purpose of generating the electron beam. A potential supply system 21, which is part of a controller 23 of the particle beam microscope 1, feeds an adjustable electric potential to the cathode 19 via a terminal 20. The potential supply system 21 likewise feeds an adjustable electric potential to the object holder 11 via a terminal 25. The electric potential for the object holder 11 can be the earth potential, for example. The difference between the potential of the object holder 11 and the potential of the cathode 19 determines the kinetic energy with which the electrons of the electron beam 5 are incident on the surface 15 of the object 13.

The particle beam source 3 furthermore comprises an extractor 27, to which the potential supply system 21 feeds, via a terminal 28, an electric potential selected such that electrons are extracted from the cathode 19. The cathode 19 can also be heated by a heating system, not illustrated in FIG. 1. The electrons extracted from the cathode 19 pass through a hole in the extractor 27 and form the particle beam 5. The electrons are accelerated towards an anode 29, to which the potential supply system 21 feeds a corresponding anode potential via a terminal 30. The anode 29 forms an upper end—in the proximity of the particle beam source 3—of a beam tube 31, through which the particle beam 5 passes. A lower end of the beam tube 31 is arranged in the proximity of the object plane 9, such that the electrons of the particle beam 5 with the kinetic energy with which they enter the beam tube 31 in an accelerated manner through the anode 29 pass close up to the object 13. Between the lower end of the beam tube 31, which is at the potential of the anode 29, and the object 13, which is at the potential of the object holder 11, the electrons are retarded, such that they are incident on the surface of the object 13 with the kinetic energy determined by the potential difference between the cathode 19 and the object holder 11.

Prior to incidence on the object 13, the particle beam 5 is focused by the objective lens 7. Between the particle beam source 3 and the objective lens 7, further particle-optical devices, not illustrated in FIG. 1, such as a condenser lens, an aperture stop, deflectors for adjusting the particle beam 5 and a stigmator, for example, can be provided in order to influence and shape the particle beam 5, such that the spot illuminated by the particle beam 5 on the surface 15 of the object 13 is as small as possible. A finely focused particle beam 5 that illuminates a small beam spot enables a high spatial resolution of the particle beam microscope 1. Further, one or more beam deflectors are provided, for example in the region of the objective lens 7, in order to displace the incidence location 17 of the particle beam 5 on the surface 15 of the object 13.

The objective lens 7 provides a magnetic field for focusing the particle beam 5. For this purpose, the objective lens 7 comprises a magnetic yoke 33 arranged rotationally symmetrically around a principal axis 35 of the particle beam microscope 1. The beam path of the particle beam 5 extends substantially along the principal axis 35 and thus passes through the objective lens 7 along the principal axis 35. The magnetic yoke 33 comprises an upper pole end 37 and a lower pole end 39. A solenoid 41 is partly enclosed by the magnetic yoke 33 with the pole ends 37, 39. The solenoid 41 is fed an electrical excitation current by the controller 23. The current generates a magnetic field that travels substantially in the magnetic yoke 33 and emerges from the magnetic yoke 33 at the pole ends 37, 39 and acts on the particle beam 5 in such a way that the latter is focused.

The lower pole end 39 is arranged in the proximity of the object plane 9 and has a central hole, through which the particle beam 5 passes. The lower pole end 39 is also at an adjustable electric potential fed to the magnetic yoke 33 via a terminal 43 by the potential supply system 21. The potential of the lower pole end 39 can be equal to or different from the potential of the object holder 11. However, the electrons of the particle beam 5 are retarded, as described above, on their path between the lower end of the beam tube 31 and the surface 15 of the object 13. This retardation is brought about by an electric field determined inter alia by the potential difference between the beam tube 31 and the lower pole end 39 or the object holder 11. This electric retardation field likewise has a focusing effect on the particle beam 5, such that the latter is focused by the joint effects of the magnetic field and this electrostatic field.

Furthermore, electrostatic or magnetic beam deflectors, not illustrated in FIG. 1, are provided in the region of the objective lens 7 and are excited by the controller 23 in order to deflect the particle beam 5, such that the incidence location 17 of the particle beam 5 on the surface 15 of the object 13 can be varied in a targeted manner. In particular, by way of the control of the beam deflectors, the controller 23 can scan the incidence location 17 over a specific region of the surface 15 of the object 13, wherein the particles to be detected arise during the scanning at the respective incidence locations 17 on account of the interaction of the particles of the particle beam 5 with the object 13. These particles to be detected comprise electrons that emerge from the object 13 with different kinetic energies. In accordance with a conventional classification, a distinction is made between secondary electrons and backscattered electrons. The secondary electrons, upon emerging from the surface 15 of the object 13, have kinetic energies of a few electron volts, for example up to 50 eV, while the backscattered electrons typically have a significantly higher kinetic energy that may be equal to the kinetic energy with which the electrons of the particle beam 5 are incident on the object 13. Both kinds of electrons are intended to be able to be detected effectively by the particle beam microscope 1.

For this purpose, the particle beam microscope 1 comprises a first scintillator 51 and a second scintillator 53, and also a first light detector 55 and a second light detector 57.

The first scintillator 51 comprises a body made of a scintillator material, for example a single-crystal YAP scintillator material or a layer made of a powdery P47 scintillator material. The body made of the scintillator material has a plate-type form with a main surface 45 facing the object plane 9 and a main surface 46 facing the particle beam source 3. The plate made of scintillator material can have a circular outer circumference or a differently shaped outer circumference and has a hole which is centred relative to the axis of symmetry 35 and through which the particle beam 5 passes. In the embodiment shown in FIG. 1, as viewed along the beam path of the particle beam 5, the first scintillator 51 is arranged between the end of the beam tube 31 in the proximity of the object plane 9 and the object plane 9. In particular, the lower pole end 39 of the objective lens 7 is also arranged between the first scintillator 51 and the object plane 9. However, the lower pole end 39 of the magnetic yoke 33 of the objective lens 7 need not be arranged between the first scintillator 51 and the object plane 9. The first scintillator 51 could also be arranged within the beam tube 31, i.e. between the anode 29 and the end of the beam tube 31 in the proximity of the object plane 9. The first scintillator 51 has a terminal 52, via which the first scintillator 51 and thus the surfaces 45 and 46 thereof can be brought to an adjustable potential relative to the potential of the beam tube 31 and the object holder 11 or the lower pole end 39 by the potential supply system 21. In the exemplary embodiment of the particle beam microscope 1 shown in FIG. 1, as viewed along the beam path of the particle beam 5, a ring electrode 56 with an opening centred with respect to the principal axis 35 is also provided between the first scintillator 51 and the object plane 9. The potential supply system 21 likewise feeds an adjustable electric potential to the ring electrode 56 via a terminal 58. The electric fields generated by the potentials of the beam tube 31, the first scintillator 51, the ring electrode 56, the lower pole end 39 and the object holder 11 influence firstly the electrons of the particle beam 5 on their path towards the object 13 but also the secondary electrons and backscattered electrons that emerge from the object 13 at the incidence location 17 of the particle beam 5 on the object 13. In particular, these electric fields accelerate the secondary electrons which emerge from the object 13 and which initially have a relatively low kinetic energy, in such a way that they are guided away from the object 13 and accelerated to an extent such that their kinetic energy is high enough to penetrate into the scintillator material of the first scintillator 51 or second scintillator 53 and to generate light there which is detectable by the light detectors 55 and 57.

If the electric potential fed to the object holder 11 via the terminal 25 is denoted by V1, the potential fed to the first scintillator 51 via the terminal 52 is denoted by V2 and the electric potential fed to the beam tube 31 via the terminal 30 is denoted by V3, then the electric potentials V1, V2 and V3 can advantageously be chosen such that they satisfy the following relations: V2 >V1, V3 >V1 and V2 >V3. Moreover, if the electric potential fed to the ring electrode 56 via the terminal 58 is denoted by V4, then it can furthermore advantageously be chosen such that the relations V4 >V1 and V4 >V2 are satisfied.

According to one example, the object holder 11 is at earth potential, with the result that V1 equals 0 V. The potential of the cathode 19 is-1 kV in this example, with the result that the kinetic energy of the electrons of the particle beam is 1 keV when incident on the surface 15 of the object 13. Furthermore, in this example, the potential V2 of the first scintillator 51 has a value of 9 kV, the potential V3 of the inner wall 85 of the beam tube 31 has a value of 8 kV and the potential V4 of the ring electrode 56 has a value of 10 kV.

Electrons which emerge from the object 13 with comparatively low kinetic energy, i.e. primarily the so-called secondary electrons, are accelerated in the above-described electrostatic fields above the object 13 away from the object 13 towards the particle beam source 3, pass through the central opening in the first scintillator 51 and enter the beam tube 31 via the lower end thereof. With the reference sign 61, one such electron is represented by its trajectory by way of example. This electron 61 departs from the principal axis 35 to such an extent that it impinges on the second scintillator 53 and penetrates into the body of the second scintillator 53. The body of the second scintillator 53 can be formed from the same scintillator material as the scintillator material of the first scintillator 51 or from a different scintillator material thereto.

The second scintillator 53 has a drilled hole 63 centred with respect to the principal axis 35, the beam path of the particle beam 5 extending through the second scintillator 53 through the drilled hole. The electron 61 arriving from the object plane 9 passes through a mirror layer 65, which is described below, and penetrates into the second scintillator 53 through a surface 72 of the second scintillator 53 facing the object plane 9. The electron 61 generates light at an interaction location 67 within the body of the second scintillator 53. An exemplary trajectory 69 of such light is depicted in FIG. 1.

This light 69 emerges from the second scintillator 53 at an opposite main surface 71 thereof in relation to the mirror layer 65 and enters a light guide 73. A first surface region 70 of the light guide 73 is in surface contact with the body of the second scintillator 53 at the surface 71 thereof or is at a small distance therefrom, such that the light guide 73 is optically coupled to the second scintillator 53 and a high proportion of the light generated in the second scintillator 53 crosses into the light guide 73 through the surface 71 of the second scintillator 53 and the first surface region 70 of the light guide 73. The light guide 73 has a second surface region 75 and further surface regions 76, at which the light is internally reflected and can pass to the light detector 57 in order to be detected by the latter. The second surface region 75 may also be rendered reflective for the purpose of improving the reflection of the light, for example by virtue of a reflective metal layer being applied to the surface region 75.

The light detector 57 generates electrical signals representing the detected light, and outputs the detection signals via a terminal 77 to the controller 23 of the particle beam microscope 1.

The second surface region 75 of the light guide 73 is situated opposite the first surface region 70 of the light guide 73 and has a surface normal 78 that is at an angle α with respect to the beam direction of the particle beam 5. The angle α can be in a range of 0° to 70°, for example. In particular, the angle α can be less than 45°. The light guide 73 also has a drilled hole 79, which is aligned with the drilled hole 63 of the second scintillator 53 and through which the beam path of the particle beam 5 extends.

With the reference sign 81, an electron that emerges from the object 13 with higher kinetic energy, for example a so-called backscattered electron, is represented by its trajectory by way of example in FIG. 1. On account of its higher kinetic energy, the electron 81 can depart further from the principal axis 35 of the particle beam microscope 1 than the electron with lower energy which is denoted by the reference sign 61 by way of example and which moves with just a low velocity component transversely with respect to the principal axis 35 and therefore passes through the central hole in the first scintillator 51. The electron 81 departs further from the principal axis 35 than would correspond to the radius of the central hole in the first scintillator 51 and therefore impinges on the body of the first scintillator 51 and penetrates into the latter.

The electron 81 generates light at an interaction location within the first scintillator 51. An exemplary trajectory 83 of a light beam arising in the process is depicted in FIG. 1. The light beam 83 impinges on an inner wall 85 of the beam tube 31 and is reflected twice at this inner wall 85 before it impinges on the surface of the mirror 65, at which there occurs a renewed reflection towards a light guide 86, into which the light beam 83 penetrates and is guided towards the light detector 55 which detects the light beam 83 and converts the latter into an electrical signal which is output to the controller 23 of the particle beam microscope 1 via a terminal 87 of the light detector 55.

The two reflections of the light beam 83 at the inner wall 85 of the beam tube 31 are by way of example. The number of reflections can be greater than two, and the light generated in the first scintillator 51 can also impinge directly on the mirror 65 or pass to the mirror 65 after only one reflection at the inner wall 85 of the beam tube 31. In order to improve the reflection properties of the inner wall 85 of the beam tube 31, the inner wall is processed so as to be a mirror surface. This processing can comprise polishing of the inner wall 85. In particular, the processing can be effected such that an average surface roughness Ra of the inner wall is less than 0.4 μm.

As is evident from FIG. 1, the inner wall 85 of the beam tube 31 in the region viewed along the beam path of the particle beam 5 between the second scintillator 53 or the mirror 65 and the first scintillator 51 is embodied as a surface having a conical shape. In particular, the beam tube 31 at its end in the proximity of the object plane 9 or the first scintillator 51 has a cross-sectional area measured perpendicularly to the principal axis 35 which is smaller than 0.5 times the cross-sectional area of the beam tube 31 in a cross-sectional plane 91 in the proximity of the second scintillator 53. In particular, the cross-sectional area of the beam tube 31 increases continuously from its end in the proximity of the object plane 9 towards the plane 91.

The conical shaping of the inner wall 85 of the beam tube 31 has the effect that light beams which emerge from the first scintillator 51 in a direction across the principal axis 35, i.e. at an angle and not parallel to the principal axis 35, are aligned in the direction of the principal axis 35 to a greater degree with each reflection at the conical inner wall 85 and then, after the reflection at the surface of the mirror 65, impinge almost perpendicularly on a surface 93 of the light guide 86. A smaller portion of the light impinging almost perpendicularly on the surface 93 of the light guide 86 is reflected at the surface 93 compared with light that impinges on the surface 93 at a greater angle with respect to the perpendicular to the surface. The conical shape of the inner wall 85 of the beam tube 31 thus has the effect that the proportion of the light generated in the first scintillator 51 which penetrates into the light guide 86 is increased, thereby also increasing the probability of detection of electrons by the first scintillator 51.

The surface of the mirror layer 65 is oriented relative to the principal axis 35 such that a surface normal of the mirror 65 forms an angle β with the principal axis 35, the angle being approximately 40° in the example in FIG. 1. In general, the angle β can be in a range of between 25° and 65° or between 30° and 60°. In the example illustrated in FIG. 1, a surface normal to the surface 93 of the light guide 86 is oriented at an angle of 90° with respect to the principal axis 35.

In the example shown in FIG. 1, the first surface region 70 of the light guide 73 is parallel to the surface of the mirror layer 65, such that the first surface region 70 of the light guide 73 is also oriented at the angle β with respect to the principal axis 35. Furthermore, the first surface region 70 is not far away from the second surface region 75 of the light guide 73, such that the two surface regions 70 and 75 delimit a part of the light guide 73 which has a conical shape. A shortest distance between the first surface region 70 and the second surface region 75 is smaller than 5 mm or smaller than 3 mm, for example. An opening angle γ can be defined as an angle between the surface normal of the first surface region 70 and the surface normal of the second surface region 75. The opening angle γ is for example in a range of between 15° and 55° and in particular in a range of between 20° and 50°.

In the case of the particle beam microscope 1, principally secondary electrons pass through the central opening of the first scintillator 51 to the second scintillator 53 in order to generate light therein, which is finally detected using the light detector 57. Substantially backscattered electrons pass to the first scintillator 51 and are used by the first scintillator 51 to generate light which is possibly reflected after one or more reflections at the inner wall 85 of the beam tube 31 via the mirror 65 towards the light detector 55 in order to be detected by the latter. In this case, the first scintillator 51 is arranged in relative proximity to the object plane 9, such that backscattered electrons that emerge from the surface 15 of the object 13 at the location 17 at a relatively large solid angle reach the first scintillator 51. The particle beam microscope 1 thus has a comparatively high detection probability for backscattered electrons emerging from the object 13.

As is evident from FIG. 1, both electrons 61, by which the second scintillator 53 generates light, and light 83 generated by the first scintillator 51 pass through the interior of the beam tube 31 in the region between the second scintillator 53 and the lower end of the beam tube 31 in the proximity of the object plane 9. In particular, both the electrons 61 arriving from the object plane 9, by which the second scintillator 53 generates light 69, and the light 83, which is generated by the first scintillator 51 and detected by the light detector 55, pass through for example the cross-sectional area arranged in the plane 91 and within the beam tube 31. The beam path of the electrons 61, by which the second scintillator 53 generates light 69, overlaps with the beam path of the light 83 generated by the first scintillator 51, for example in the plane 91 since the plane contains locations through which both the electrons 61 and the light 83 pass. Accordingly, the beam tube 31 serves not only to house the beam path of the particle beam 5 but also as a transportation tube for the electrons used by the second scintillator 53 to generate light and for the light beams 83 which were generated by the first scintillator 51 and are detected by the light detector 55.

Further embodiments are explained below with reference to the figures. In this case, components which are similar to components of the embodiment explained with reference to FIG. 1 in regard to their structure and/or function are denoted by the same reference sign but provided with an additional letter for differentiation purposes. For an understanding of the individual components whose description is not repeated or is only partly repeated, reference should be made to the description of the preceding embodiments and the introduction to the description.

A particle beam microscope 1a shown in FIG. 2 has a similar set-up to the particle beam microscope explained with reference to FIG. 1 by virtue of the fact that it comprises a particle beam source 3a and an objective lens 7a in order to focus a particle beam 5a generated by the particle beam source 3a in an object plane 9a. The particle beam source 3a likewise comprises a cathode 19a and an extractor 27a. The particle beam 5a likewise passes through a beam tube 31a, the lower end of which is arranged within the objective lens 7a. The objective lens 7a generates a magnetic field that focuses the particle beam 5a with the aid of a coil 41a, which is partly enclosed by a magnetic yoke 33a having an upper pole end 37a and a lower pole end 39a.

A first scintillator 51a is arranged between the lower end of the beam tube 31a and the object plane 9a. A ring electrode 56a can likewise be arranged between the first scintillator 51a and the object plane 9a. Besides the first scintillator 51a arranged in the proximity of the object plane 9a, the particle beam microscope 1a comprises a second scintillator 53a, which is arranged at a greater distance from the object plane 9a. The first scintillator 51a serves principally to generate light by way of backscattered electrons 81a, while the second scintillator 53a principally serves to generate light by way of secondary electrons that have passed through a central opening of the first scintillator 51a.

The embodiment shown in FIG. 2 differs from that in FIG. 1 substantially by virtue of the fact that at least one common light detector 101 is provided for the detection of the light generated by the first scintillator 51a and for the detection of the light generated by the second scintillator 53a. In simple embodiments, the at least one common light detector can be designed such that it detects the light generated by the first scintillator 51a and the light generated by the second scintillator 53a without discriminating between these two types of light. In other embodiments, as described below, the at least one common light detector is designed such that it detects the light generated by the first scintillator 51a and the light generated by the second scintillator 53a in such a way that there is a discrimination between these two types of light. For example, this can be implemented by virtue of the two types of light having different wavelengths and the common light detector being configured to discriminate between the two types of light on the basis of the wavelength. For example, different colour filters may be selectively arranged upstream of the light detector in the beam path of the light, in order to successively detect first the one type of light and then the other type of light. Further, the at least one common light detector may comprise a plurality of light detectors, wherein different colour filters are arranged in the beam paths upstream of the light detectors, the colour filters allowing one type of light to pass through to the one light detector and allowing the other type of light to pass through to the other light detector.

The electron which emanates from an incidence location 17a of the particle beam 5a at the surface of an object 13a and which is represented by the trajectory 61a by way of example in FIG. 2 penetrates into the second scintillator 53a and generates light at an interaction location 67a. An exemplary light beam 69a generated by the electron 61a is depicted in FIG. 2. This light beam 69a emerges from the second scintillator 53a at its surface 71a facing away from the object plane 9a and enters a light guide 103 whose surface is in contact with the surface of the second scintillator 53a such that the light guide 103 is optically coupled to the second scintillator 53a. The light beam 69a is reflected one or more times at inner surfaces of the light guide 103 before it impinges on the light detector 101, which detects the light and outputs a detection signal corresponding to the light to a controller 23a of the particle beam microscope 1a via a terminal 107.

Besides the secondary electrons 61a impinging on the second scintillator 53a, light beams 83a generated by electrons in the first scintillator 51a also pass through the space within the beam tube 31a and between the first scintillator 51a and the second scintillator 53a. These light beams 83a are reflected if appropriate one or more times at an inner wall 85a of the beam tube 31a before they impinge on the second scintillator 53a. However, unlike the second scintillator 53 in the embodiment in FIG. 1, the second scintillator 53a does not bear a mirror surface, and so the light 83a generated by the first scintillator 51a can pass through the second scintillator 53a and can enter the light guide 103. The light guide 103 has a surface region 104 situated opposite the second scintillator 53a, and also further surface regions 105. In the light guide 103, the light 83a is reflected one or more times at the surface regions 104, 105 of the light guide in order then to be detected by the light detector 101. The surface region 104 may also be rendered reflective for the purpose of improving the reflection of the light, for example by virtue of a reflective metal layer being applied to the surface region 104.

Within the beam tube 31a, this embodiment also includes a cross-sectional area oriented across the principal axis 35a in the region along the principal axis 35a between the first scintillator 51a and the second scintillator 53a, in which cross-sectional area the beam path of the electrons 61a, by which the second scintillator 53a generates light, overlaps with the beam path of the light generated by the first scintillator 51a and detected by the detector 101.

A surface 54 of the second scintillator 53a is oriented orthogonally to the direction of a principal axis 35a of the objective lens 7a. Consequently, an angle β between a surface normal to the surface 54 and the direction of the principal axis 35a is 0° in the example in FIG. 2, while the corresponding angle β in the embodiment in FIG. 1 was 40°. Other possibilities for the selection of the angle β in the embodiment in FIG. 2 are such that the angle β is greater than 0° but less than 20°, in particular less than 10° or in particular less than 5°. An angle γ between a surface normal 78a of the surface 104 of the light guide 103 opposite the second scintillator 53a and the surface normal of the surface region of the light guide 103, to which the second scintillator 53a is coupled, is 15° to 55°, in particular 20° to 50° or in particular less than 45°. The light guide 103 also has a drilled hole 79a aligned with a drilled hole 63a in the second scintillator 53a in order to allow the beam path of the particle beam 5a to pass through the light guide 103 and the second scintillator 53a.

The surface region 104 of the light guide 103 also has a function as a mirror surface for the light 83a which has been generated by the first scintillator 51a and has passed through the second scintillator 53a, in order to reflect this light towards the detector 101. The surface region 104 has the surface normal 78a that is at an angle α with respect to the beam direction of the particle beam 5a. The angle α can be for example in a range of between 15° and 55° and in particular in a range of between 20° and 50° or can be in particular less than 45°. As in the exemplary embodiment shown in FIG. 1, in the exemplary embodiment in FIG. 2 as well, the light guide 103 forms a wedge whose opening angle γ is defined as the angle between the surface normal 78a of the surface region 104 of the light guide 103 and the surface normal of that surface region of the light guide 103 which is coupled to the second scintillator 53a. The opening angle γ is for example in a range of between 15° and 55° and in particular in a range of between 20° and 50°.

It is noted that the attached figures are schematic and serve to explain the functions and basic structure of the embodiments. In particular, the figures have not been designed to reproduce geometric dimensions of the embodiments true to scale. In particular, the angles explained above are reproduced merely in principle and not with true values in the figures.

Besides the first scintillator 51a and the second scintillator 53a, the particle beam microscope 1a also comprises a further detection system for electrons emerging from the object 13a. The detection system comprises an electron detector 111 and a first grid 113 and a second grid 115, which are arranged in the beam path of the electrons emitted by the object 13a between the object plane 9a and the detector 111. Electrons that have passed through the opening in the scintillator 51a and the drilled holes 63a and 79a in the scintillator 53a and the light guide 103, respectively, can impinge on the electron detector 111 in order to be detected by the latter. A potential supply system 21a applies adjustable potentials to the grids 115 and 113. These potentials can be varied in order to select the energy of the electrons that reach the detector 111. In this case, a minimum kinetic energy of the electrons that can be detected by the detector 111 is adjusted by way of a potential difference between the object and the grid 113. By changing the potential at the grid 113, it is possible to select the kinetic energy of the electrons that reach the grid 113 and pass through the latter in order subsequently to be detected by the detector 111.

1. A particle beam microscope, comprising:
a particle beam source configured to generate a particle beam;
an objective lens configured to focus the particle beam in an object plane;
a first scintillator configured to generate light via electrons arriving from the object plane;
a second scintillator configured to generate light via electrons arriving from the object plane; and
a first light detector configured to detect light generated by the first scintillator and/or the second scintillator;
wherein:
a shortest distance of the second scintillator from the object plane is greater than a shortest distance of the first scintillator from the object plane;
a first beam path and a second beam path overlap one another in a cross-sectional area between the first scintillator and the second scintillator and across a beam direction of the particle beam;
the first beam path is a beam path of electrons arriving from the object plane by which the second scintillator generates light; and
the second beam path is a beam path of light generated by the first scintillator and detected by the first light detector.

2. The particle beam microscope of claim 1, further comprising a mirror surface,
wherein:
the first light detector is configured to detect the light generated by the first scintillator; and
the mirror surface is in a beam path between the first scintillator and the first light detector to reflect the light generated by the first scintillator.

3. The particle beam microscope of claim 2, wherein the second scintillator supports the mirror surface so that the light generated by the first scintillator is reflected at the mirror surface without passing through the second scintillator.

4. The particle beam microscope of claim 2, wherein the mirror surface is electrically conductive.

5. The particle beam microscope of claim 2, wherein the second scintillator comprises a single-crystal scintillator comprising a surface defining at least a portion of the mirror surface.

6. The particle beam microscope of claim 2, wherein an angle between a surface normal of the mirror surface and the beam direction of the particle beam is between 25° and 65°.

7. The particle beam microscope of claim 2, further comprising a second light detector, wherein the second light detector is configured to detect the light generated by the second scintillator.

8. The particle beam microscope of claim 7, further comprising a light guide between the second scintillator and the second light detector in a beam path of the light generated by the second scintillator.

9. The particle beam microscope of claim 8, wherein the second scintillator comprises a surface optically coupled to a first surface region of the light guide.

10. (canceled)

11. The particle beam microscope of claim 10, wherein a shortest distance between the first surface region and the second surface region is less than 5 mm.

12. The particle beam microscope of claim 1, wherein the second scintillator is in a beam path between the first scintillator and the light detector so that the light generated by the first scintillator passes through the second scintillator.

13. The particle beam microscope of claim 12, wherein a surface region of the second scintillator is electrically conductive and configured to transmit the light generated by the first scintillator.

14. (canceled)

15. The particle beam microscope of claim 12, further comprising a light guide in a beam path between the second scintillator and the light detector.

16. The particle beam microscope of claim 15, wherein the second scintillator comprises a surface optically coupled to a first surface region of the light guide.

17. (canceled)

18. (canceled)

19. The particle beam microscope of claim 1, wherein the light guide comprises a hole, and a portion of a beam path of the particle beam extends through the hole.

20. The particle beam microscope of claim 1, wherein the second scintillator comprises a hole, and a portion of a beam path of the particle beam extends through the hole.

21. The particle beam microscope of claim 1, further comprising a beam tube, wherein a portion of a beam path of the particle beam between the first and second scintillators extends through the beam tube, and an inner wall of the beam tube is electrically conductive.

22. (canceled)

23. The particle beam microscope of claim 22, wherein:
a cross section of the beam tube at an end of the region in proximity to the first scintillator has a first cross-sectional area in a plane orthogonal to the beam direction of the particle beam;
the cross section of the beam tube at an end of the region in proximity to the second scintillator has a second cross-sectional area in a plane orthogonal to the beam direction of the particle beam; and
the second cross-sectional area is at least two times greater than the first cross-sectional area.

24. The particle beam microscope of claim 23, wherein the cross section of the beam tube increases continuously from the end in proximity to the first scintillator to the end of the region in proximity of the second scintillator.

25. (canceled)

26. A particle beam microscope, comprising:
a particle beam source configured to generate a particle beam;
an objective lens configured to focus the particle beam in an object plane;
a first scintillator configured to generate light via electrons arriving from the object plane;
a light detector configured to detect light generated by the first scintillator;
a mirror surface configured to reflect the light generated by the first scintillator towards the light detector; and
a beam tube,
wherein:
a portion of a beam path of the particle beam between the mirror surface and the first scintillator extends through the beam tube;
an inner wall of the beam tube is conductive; and
in a region of the beam tube between the mirror surface and the first scintillator, the inner wall of the beam tube comprises a mirror surface having a mean surface roughness of less than 0.4 μm.

27.-31. (canceled)
